(19) United States
(12) Patent Application Publication
(10) Pub. No.: US 2024/0195375 A1
(43) Pub. Date: Jun. 13, 2024

(54) METHOD FOR TIA TRANSIMPEDANCE CONTROL

(71) Applicant: Nokia Solutions and Networks Oy, Espoo (FI)

(72) Inventors: Lorenzo Lotti, Brooklyn, NY (US); Mark Ferriss, Tarrytown, NY (US); Alexander Rylyakov, Staten Island, NY (US)

(21) Appl. No.: 18/356,519

(22) Filed: Jul. 21, 2023

Related U.S. Application Data
(60) Provisional application No. 63/431,925, filed on Dec. 12, 2022.

(51) Int. Cl. H03G 3/30; H03F 1/30; H03F 1/32; H03F 3/45; H03G 1/00

(52) U.S. Cl. CPC H03G 3/3084; H03F 1/301; H03F 1/3211; H03F 3/45475; H03G 1/0088

(57) ABSTRACT

A transimpedance amplifier (TIA) includes a voltage amplifier and a first set of variable-resistors connected in parallel as a variable shunt feedback to the voltage amplifier. A control circuit is connected to control the variable resistors of the first set in a manner responsive to a TIA gain control voltage V_{GC}. The control circuit includes a ramp generator and a reference set of variable-resistors connected in parallel. The ramp generator is configured to generate, responsive to an output voltage of the control circuit, a plurality of ramp voltages such that each of the voltages adjusts a corresponding one of the variable-resistors of the first set and of the reference set.

### CROSS-REFERENCE TO RELATED APPLICATIONS

This application claims the benefit of the U.S. Provisional Patent Application No. 63/431,925, filed on Dec. 12, 2022, which is incorporated herein by reference in its entirety.

### FIELD OF INVENTION

Various example embodiments relate to variable-gain trans-impedance amplifiers and coherent optical receivers using such trans-impedance amplifiers.

### BACKGROUND

Trans-impedance amplifiers (TIAs) are used in high speed fiber optic communication systems to provide a link between optical-to-electrical converters, e.g. photodetectors (PD), and the downstream electronics. A TIA converts the current coming from the PD into a voltage, thus providing transimpedance gain (ZT). This voltage is typically fed to an ADC, and the resulting signal may be processed in the digital domain. The TIA is desirably linear, and has a well-controlled gain in the relevant operating range, so that the ADC receives a voltage that is an about linear representation of the current from the PD, and has a magnitude within the dynamic range of the ADC.

### SUMMARY

An aspect of the present disclosure provides an apparatus comprising a transimpedance amplifier (TIA). The TIA comprises a voltage amplifier, a first set of variable-resistors connected in parallel as a variable shunt feedback to the voltage amplifier, a control circuit connected to control the variable resistors of the first set in a manner responsive to a TIA gain control voltage V_{GC}, and a ramp generator. The control circuit comprises a reference set of variable-resistors connected in parallel. The ramp generator is configured to generate, responsive to an output voltage of the control circuit, a plurality of ramp voltages such that each of the voltages adjusts a corresponding one of the variable-resistors of the first set and the reference set.

In some implementations of the above apparatus, each of the variable-resistors of the first set comprises a field-effect transistor (FET), channel resistances of different ones of the FETs having different values for a same applied gate voltage, ratios of different ones of said values being approximately equal to nonzero integer powers of two.

In some implementations of the above apparatus, each of the variable-resistors of the first set comprises a FET, gate widths of different ones of the FETs having different values (e.g. “W”, “2 W”, “4 W”, “8 W”), ratios of different ones of said values being approximately equal to nonzero integer powers of two.

In any of the above implementations, at least some of the variable-resistors of the first set may comprise each a resistor in series with the FETs of a corresponding one of the variable resistors of the first set, ratios of resistances of said resistors of different ones of the variable resistors being approximately equal to nonzero integer powers of two.

In any of the above implementations, each of the variable-resistors of the reference set comprises a FET, channel resistances of different ones of the field effect transistors of the reference set being about the same for a same gate voltage applied thereto. In some of these implementations, each of the variable-resistors of the reference set comprises a resistor in series with a corresponding one of the FETs of the reference set, said resistors of the reference set having about a same resistance.

In any of the above implementations, each of the variable-resistors of the reference set comprises a FET, gate widths of different ones of the FETs of the reference set being about the same.

In any of the above implementations, the gain control circuit may comprise a voltage-controlled current source configured to transmit a current proportional to the TIA gain control voltage (V_{GC}) to an input of the reference set.

In any of the above implementations, the gain control circuit may comprise an operational amplifier (OpAmp) having a first input connected to the reference set and a second input connected to a reference voltage V_{REF}. In some of such implementations, the apparatus is configured to vary a voltage gain A_{V} of the OpAmp responsive to the TIA gain control voltage V_{GC}. In some of such implementations, the control circuit is configured to vary the voltage gain A_{V} of the OpAmp approximately proportionally to an inverse of the resistance of the reference set.

In any of the above implementations, the gain control circuit may be configured to vary a resistance of the first set in an approximately exponential relationship to the gain control voltage VGC.

In any of the above implementations, the ramp generator may comprise a set of voltage-controlled current sources, each configured to provide an output current to a resistor to generate one of the ramp voltages, each of the output currents being based on the output voltage of the control circuit and an offset voltage V_{REFj}, the offset voltages V_{REFj} being different for different ones of the ramp voltages.

An aspect of the present disclosure provides a coherent optical receiver comprising an optical hybrid, a pair of photodiodes, and the apparatus of any of the above implementations. Each of the photodiodes is configured to receive light from a corresponding output of the optical hybrid, and is connected to a corresponding input of the TIA.

### BRIEF DESCRIPTION OF THE DRAWINGS

Embodiments disclosed herein will be described in greater detail with reference to the accompanying drawings which represent preferred embodiments thereof, in which like elements are indicated with like reference numerals, and wherein:

FIG. 1 is a schematic block diagram of a coherent optical receiver where the TIA(s) of the present disclosure may be used;

FIG. 2 is a schematic block diagram of a TIA circuit that may be used in the coherent optical receiver of FIG. 1;

FIG. 3 is a circuit diagram of a TIA with a replica bias circuit for controlling feedback resistor RF;

FIG. 4 is a circuit diagram of a TIA with a closed-loop replica bias control circuit with improved feedback resistor RF control accuracy;

FIG. 5A is a schematic diagram illustrating a segmented feedback resistor bank of a TIA;

FIG. 5B is a schematic block diagram illustrating a ramp generator for generating gate control voltages for the segmented feedback resistor bank of FIG. 5A;

FIG. 5C illustrates the gate control voltages generated by the ramp generator of FIG. 5B versus the gain control voltage V_{GC};

FIG. 6A is a diagram of an example TIA circuit with binary weighted feedback resistance bank and closed-loop resistance control using a binary weighted reference resistance bank;

FIG. 6B is a circuit diagram of a voltage controlled current source of a ramp voltage generator of FIG. 6A;

FIG. 6C is a graph illustrating the operation of the ramp voltage generator of FIG. 6A showing the dependence of gate control voltages Vgi on the output voltage V_{OA} of the RF control circuit of FIG. 6A;

FIG. 7 is a diagram of an example TIA circuit with binary weighted feedback resistance bank and modified closed-loop resistance control for dB-linear TIA transimpedance control according to an embodiment;

FIG. 8 is a diagram of an embodiment of the example TIA circuit of FIG. 7 with a tunable-gain Operational Amplifier;

FIG. 9 is an example circuit diagram of an Operational Amplifier (OpAmp) input stage having a variable transconductance;

FIG. 10 is a schematic diagram of an OpAmp gain controller;

FIG. 11 is a schematic diagram of a variable-resistance circuit for use as a TIA feedback resistor (“first set”) in the TIA circuits of FIGS. 6A, 7 and 8 according to some embodiments;

FIG. 12 is a schematic diagram of a variable-resistance circuit for use in the TIA control circuits (“reference set”) of FIGS. 7 and 8, according to some embodiments.

### DETAILED DESCRIPTION

In the following description, for purposes of explanation and not limitation, specific details are set forth, such as particular circuits, circuit components, techniques, etc. in order to provide a thorough understanding of the present invention. However, it will be apparent to one skilled in the art that the present invention may be practiced in other embodiments that depart from these specific details. In other instances, detailed descriptions of well-known methods, devices, and circuits may be omitted so as not to obscure the description of the present invention. All statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Furthermore, the following abbreviations and acronyms may be used in the present document:
ADC: Analog to Digital Converter
AGC: Automatic Gain Control
AV: voltage gain
BiCMOS: Bipolar Complementary Metal-Oxide-Semiconductor
BW: BandWidth
DSP: Digital Signal Processor
MOS: Metal-Oxide-Semiconductor
GBW: Gain BandWidth product
GDV: Group Delay Variation
IGC: gain control current
OpAmp: Operational Amplifier
PVT: Process/supply Voltage/Temperature
RF: Feedback Resistor
TIA: TransImpedance Amplifier
VCCS: Voltage-Controlled Current Source
VGC: gain control voltage
VTH: threshold voltage
ZT: transimpedance

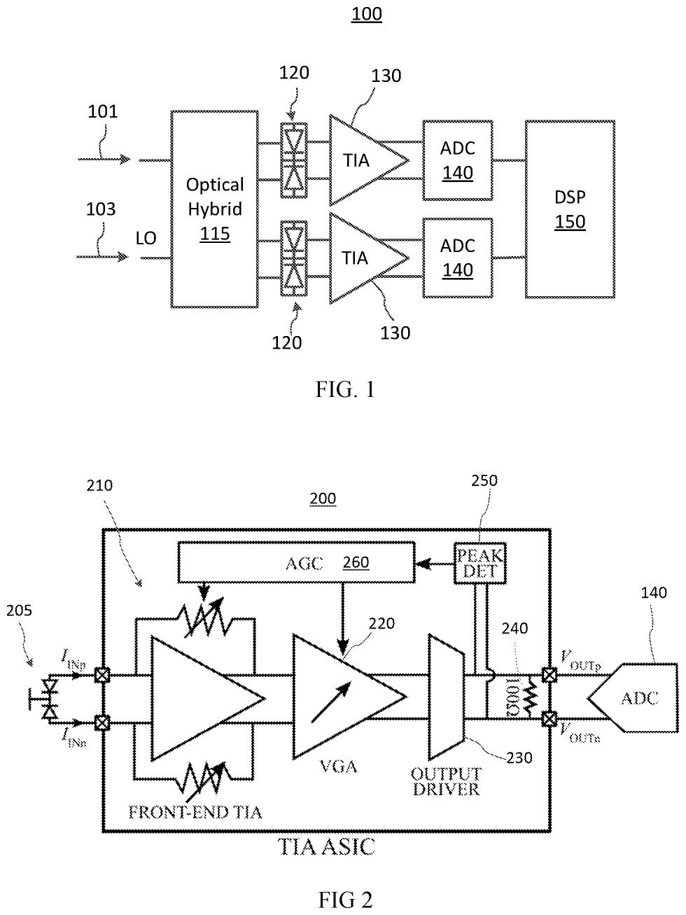

FIG. 1 illustrates a block diagram of an example coherent optical receiver 100 to which embodiments of the present disclosure may relate. An optical signal 101 received from an optical communication link (not shown) is mixed with local oscillator (LO) light 103 in an optical hybrid 115. Different mixtures of the optical signal 101 and LO light 103 from four output ports of the optical hybrid 115 are transmitted to two photodiode (PD) pairs 120. Each PD pair 120 may be suitably biased at mid-point. The two PDs of a pair measure mixtures of the received optical signal light 101 with LO light 103 with different relative phase shifts. The signals from the two PDs of a pair 120 are coupled to the differential inputs of a corresponding TIA circuit 130. Differential outputs of the TIAs 130 are provided to respective ADCs 140, which are, in turn, connected to a DSP 150 for signal processing and data de-modulation.

A block diagram of a typical TIA circuit 200 (“TIA 200”), which may be implemented e.g. as an Application-Specific Integrated Circuit (ASIC), is shown in FIG. 2. It includes a front-end TIA (FE-TIA) 210, which converts the PD current(s) I_{IN}_{ₚ}, I_{IN}_{ₙ} into a voltage signal, followed by a series of one or more Variable Gain Amplifiers (VGA) 220 to provide further voltage amplification, and an output driver 230. The output driver 230 is typically a transconductor, which drives an on-chip termination resistor 240 as well as being connected to the inputs of the ADC 140. The TIA circuit 200 may also include a peak detector 250 to measure the output swing, and an Automatic Gain Control (AGC) loop 260, which adjusts the TIA gain in order to keep the peak output swing at a desired value in the presence of slow variations of the swing of the currents I_{IN}_{ₚ}, I_{IN}_{ₙ} input to the TIA 200.

For the coherent optical receiver 100 illustrated in FIG. 1, the TIA input signal amplitude can vary suddenly by >10× (20 dB) due to events in the optical network. Such events can substantially change the optical signal propagating to an optical receiver, at a rate much lower than the baud rate or symbol rate of the optical signal. In response to such events, gain of the TIA circuit 200 may be adjusted by the AGC 260, so that the amplitude of the output signal remains about constant and remains within a desirable operating range of the ADC 140 connected to receive the output signals V_{OUT}_{ₚ}, V_{OUT}_{ₙ} of the TIA circuit 200.

In a variable-gain TIA, an accurate dB-linear, or linear-in-dB, gain control scheme may be desired. A dB-linear control may be achieved if the transimpedance (ZT) of the TIA varies exponentially with a gain control voltage (V_{GC}) signal, with the VGC signal being proportional to a logarithm of the input signal power. A dB-linear control has several benefits. First, it helps to keep the AGC loop bandwidth constant across input current variations. Second, in optical links the VGC signal may be used to monitor the magnitude of the received optical power with a good accuracy and a high dynamic range.

Furthermore, it is typically desired that the ZT vs V_{GC} characteristic has a low dependency on supply voltage and temperature, so that after a one-time calibration, the V_{GC} signal may be used to monitor a TIA input power with a suitably low drift.

Accurate, low-drift and dB-linear ZT control is not trivial in integrated TIAs. As shown in FIG. 2, there are typically multiple variable gain stages in a TIA circuit, typically including the front-end TIA (FE-TIA) 210, which converts the PD current into voltage, and one or multiple Variable Gain Amplifiers (VGA) 220. The FE-TIA 210 is commonly implemented with a shunt-feedback topology, where ZT tuning is usually achieved by placing a MOS transistor in parallel with, e.g., a fixed feedback resistor. However, the resistance of a MOS transistor in an “ON” state is not exponential versus its gate control, and depends on a threshold voltage (V_{TH}) of the transistor, which varies with temperature.

The present disclosure relates to a method and a circuit that may provide a more accurate, temperature-stable, and approximately dB-linear control of a shunt-feedback FE-TIA, e.g. using a segmented replica or reference bias scheme. “Segmented bank” herein refers to an implementation of an electrical component, e.g. a variable resistor, with multiple individual elements (or “segments”) connected in parallel to each other. The terms “bank”, “segmented bank”, and “set” may be used herein interchangeably.

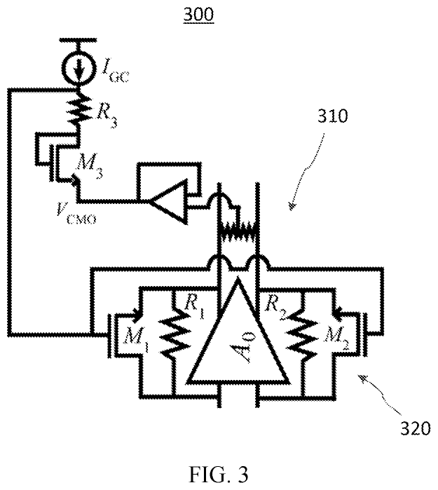

FIG. 3 illustrates a circuit 300 implementing an open-loop replica bias technique to reduce temperature dependence and improve accuracy of the TIA ZT control. This technique is typically used for controlling variable resistors in amplifiers, including TIAs. In the circuit of FIG. 3, a feedback resistor (RF) 320 of a TIA 310 having voltage gain A0 is implemented with fixed resistors R₁ and R₂ in parallel with MOS transistors M₁ and M₂. A replica diode-connected transistor M₃, in series with resistor R₃, is driven by a gain control current I_{GC} to generate a gate control voltage for the transistors M₁ and M₂. The source of the transistor M₃ is biased at the same voltage as the source of each of the transistors M₁ and M₂, through a unity-gain buffer that replicates the output common-mode DC voltage V_{CMO} of the TIA 310.

The transistor M₃ is designed to be a replica of the transistors M₁ and M₂, and is typically located in a same chip suitably close to the transistors M₁ and M₂, so that the V_{TH} of the transistor M₃ approximately tracks threshold variations of the transistors M₁ and M₂, and therefore this scheme typically reduces the sensitivity of the ZT control to temperature and process variations. However, this scheme may not provide an accurate linear or exponential control of the feedback resistor(s) RF 320, since the resistance of the transistors M₁ and M₂ may vary nonlinearly (but not exponentially) versus their respective gate-source voltage (V_{GS}).

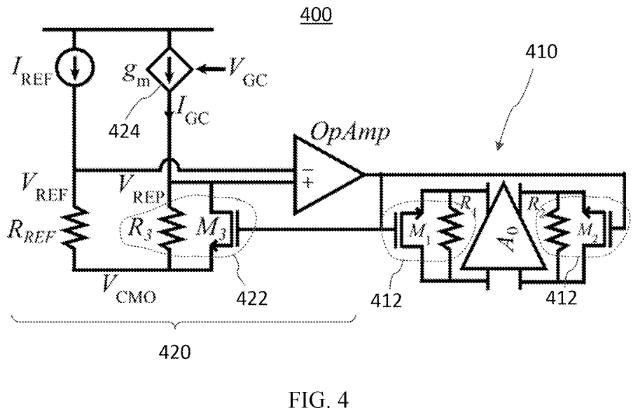

FIG. 4 illustrates a circuit 400 implementing a closed-loop replica bias control technique for an FE-TIA 410, which may enable a more accurate TIA gain control. Here the RF control circuit includes an Operational Amplifier (“OpAmp”). The controlled FE-TIA 410 is to the right of the OpAmp in FIG. 4. The closed-loop control circuitry 420, including the OpAmp and the circuit to the left of the OpAmp in FIG. 4, implements a closed-loop bias control scheme that controls the gate voltage of the transistors M₁ and M₂. The OpAmp compares a constant voltage V_{REF} with a replica voltage V_{REP}, with V_{REP} being generated by a variable current I_{GC}=gm*V_{GC}. Current I_{GC}, which is controlled by a gain control voltage V_{GC}, is provided to a replica (R₃, M₃) 422 of the variable feedback resistors 412, (R₁, M₁) and (R₂, M₂), of the TIA 410. Here, gm is the transconductance (a first derivative of the output current (I) with respect to the input voltage (V)) of a voltage-controlled current source (VCCS) circuit 424, which has an approximately linear I-V characteristic within the range of V_{GC} voltages used to tune the TIA's ZT. As a result, the I_{GC} is approximately directly proportional to the V_{GC}. This way, the closed-loop control circuit 420 adjusts the gate control voltage V_{GS} of transistors M₁ and M₂ to vary the RF inversely proportionally to V_{GC}, i.e. RF˜I/I_{GC}. As a result, this scheme may provide an approximately linear control of the TIA's ZT.

One potential drawback of the circuit of FIG. 4 is that the circuit may not be suitable for TIAs requiring an approximately linear amplification with a large dynamic range. In the circuit of FIG. 4, the gate-source voltage V_{GS} of the transistors M₁ and M₂ may vary significantly with V_{GC}, and for low values of V_{GS}, the transistors M₂ and M₃ may exhibit nonlinear resistances, thereby limiting the TIA's linearity. Herein, an element with a nonlinear resistance refers to an element whose resistance significantly depends on the voltage across the element over the operating range for the element.

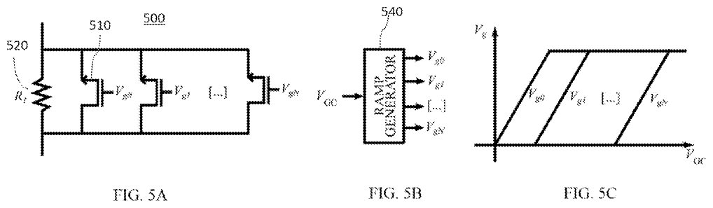

Referring to FIGS. 5A, 5B, and 5C, the linearity of a TIA's ZT may be improved by implementing the TIA feedback resistor RF with a segmented bank or set 500 of multiple transistors 510 (FIG. 5A), which may be turned on sequentially. In this manner, at any given time only a few elements (e.g. typically one element) of the RF bank 500 is operating at a suitably low gate-source voltage V_{GS} in a regime where the resistance of said element is nonlinear. The majority of the elements of the RF bank 500 are either turned off with V_{GS} close to 0 Volts, or turned on with a suitably high V_{GS} in a regime where the resistance of said element is linear. Since only one or a few elements of the RF bank 500 operate in a nonlinear regime, the impact on the ZT nonlinearity of the TIA is reduced. A ramp generator circuit 540, schematically shown in FIG. 5B as a block, generates multiple gate control voltages V_{g0}, V_{g1}, . . . , V_{gN}, which are ramped up sequentially as a function of the gain control voltage V_{GC} (FIG. 5C). Each gate control voltage V_{gi}, i=0, 1, . . . , N, is provided to the gate of the corresponding MOS transistor 510 in the bank (set) 500 of MOS transistors, which are connected in parallel with a TIA feedback resistor “R₁” 520, which may represent, e.g., “R₁” 322 or “R₂” in the TIAs of FIG. 3 or 4.

The circuit 400 of FIG. 4, with or without the segmented bank 500 of FIG. 5, provides an approximately linear control of RF. However, an approximately exponential dependence of the RF upon a gain control voltage V_{GC} may be desired for dB-linear control. One potential solution may be to generate a current I_{GC} (see, e.g., FIG. 4) that is exponentially proportional to the gain control voltage V_{GC}. This can be achieved e.g. by using a bipolar transconductor, or alternatively a MOS transistor in a subthreshold regime. However, achieving exponential transconductance over a wide dynamic range, e.g., 20 dB or greater, may be difficult. Also, the parameters of a bipolar transconductor may vary with process and temperature variations, which could limit the accuracy of such a gain control scheme. In particular, reducing temperature sensitivity may be a challenging problem and may require complex compensation circuits.

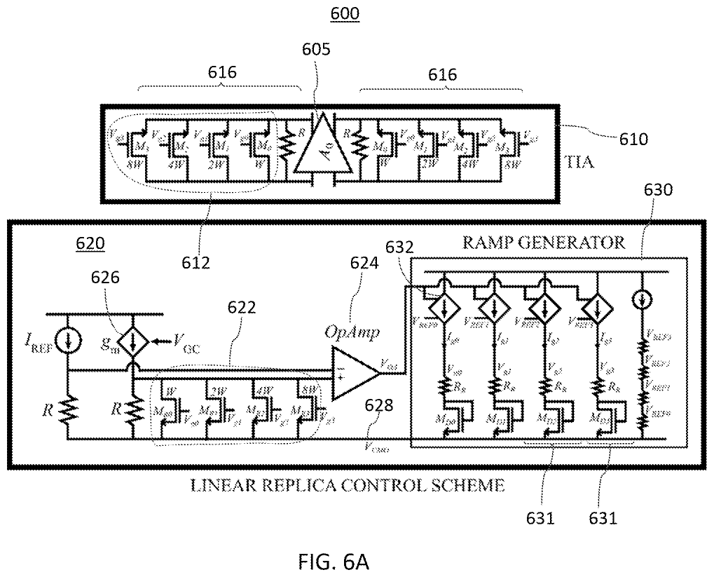

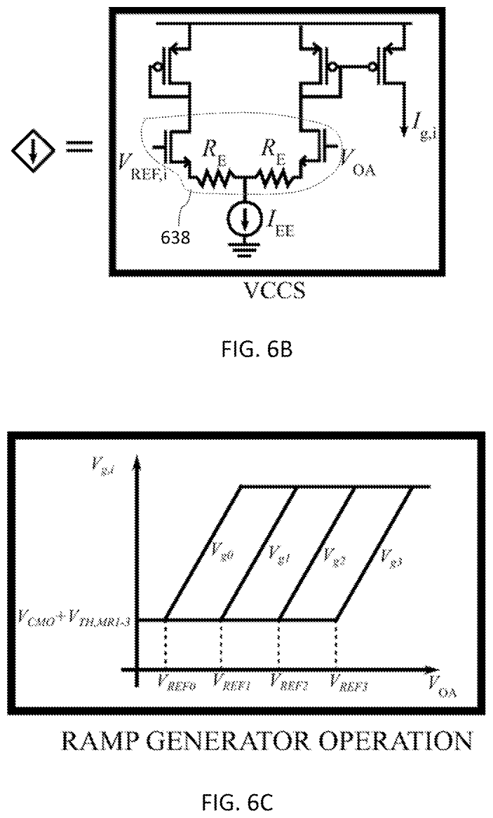

FIG. 6A illustrates an apparatus 600, e.g. an FE-TIA, having a feedback resistance control that combines a control circuit 620 with a TIA 610 that includes a voltage amplifier 605 having a feedback resistor 616 in the form of a segmented (feedback) resistor bank. The control circuit 620 is a modification of the closed-loop scheme shown in FIG. 4. In the illustrated embodiment the RF bank includes four transistors M₀, M₁, M₂, M₃ connected in parallel, which form a first set 612 of variable-resistors. The four transistors M₀-M₃ are configured to have binary-weighted channel resistances; that is, the channel resistances of different ones of the transistors M₀-M₃ of the first set 612 have different values for a same applied gate voltage, ratios of different ones of said values being approximately equal to nonzero integer powers of two. In an embodiment, the transistors M₀, M₁, M₂, and M₃ have gates with widths that are binary-weighted, i.e. W, 2 W, 4 W, 8 W, respectively. Other embodiments may have a different number N of binary-weighted transistors in the bank, where N may be smaller or greater than four; the width of the gate of the i-th transistor in such embodiments scales approximately as a power of two, i.e. ˜2ⁱ·W.

The closed-loop control circuit 620 for controlling the transistors M₀-M₃ includes a V_{GC}-controlled VCCS 626 connecting to a reference set 622 of variable-resistors implemented with transistors M_{R0}-M_{R3}, with about the same size and/or same-gate-voltage channel resistances, as the transistors M₀-M₃ of the first set 612. The closed-loop control circuit 620 is operable to generate voltages V_{g0}-V_{g3} which control the gates of transistors M₀-M₃ for tuning the feedback resistor bank 616. The negative supply rail 628 of the control circuit 620 is set to V_{CMO}, i.e. the TIA output common-mode voltage, so that the transistors M₀-M₃ and M_{R0}-M_{R3} share about the same source voltage.

The output voltage V_{OA} of the feedback OpAmp 624 is fed to a ramp generator 630 to control the gate voltages of corresponding variable-resistors of the first set 612 and of the reference set 622 sequentially, e.g. starting from the smallest one of the variable-resistors. Each element 631 of the ramp generator 630 includes a VCCS 632 configured to generate a current I_{g,i} proportional to a voltage difference (V_{OA}−V_{REF,i}), where the V_{REF,i} are reference offset voltages to the respective VCCS 632. An example circuit diagram of the VCCS 632 is illustrated in FIG. 6B. Currents I_{g,i} generated by the respective VCCSs 632 are used to generate the gate control voltages V_{g,i}. To generate the V_{g,i}'s, currents I_{g,i} may be fed to diode-connected transistors M_{Di}, which may be replicas of transistors M₁, in series with resistor R_{R}.

As shown in FIG. 6C, increasing the output voltage V_{OA} of the OpAmp 624 across its operating range results in voltages V_{g,i} being ramped up sequentially from a minimum value given approximately by (V_{CMO}+V_{TH,MDi}), where V_{TH,MDi} is the threshold voltage of the transistors M_{D,i}, to a maximum voltage given approximately by (V_{CMO}−V_{TH,MDi}+R_{R}*I_{g,i,max}), where I_{g,i,max} is the maximum current value provided by each VCCS 632.

FIG. 6B shows an example implementation of the VCCS 632, using a degenerated differential transistor pair 638 with a diode-connected load. The output current I_{g,i} is approximately proportional to (V_{OA}−V_{REF,i}) in a given range around V_{REF,i} wherein the range is defined by the degeneration resistor R_{E}. The output current values range from about zero to a maximum current that is about equal to the tail current I_{EE} of the degenerated differential transistor pair 638.

Voltages V_{REFi}, i=0, . . . , N−1, set the threshold above which the transistor M_{R0}, . . . , M_{R3} of each variable-resistor of the first set 612 is turned on, and may be set to achieve some overlap between the control voltage ramps, to avoid discontinuities in the RF vs V_{GC} transfer function. The TIA apparatus 600 of FIG. 6A may provide approximately linear and accurate RF control together with a TIA linearity offered by the segmented feedback resistor bank 616.

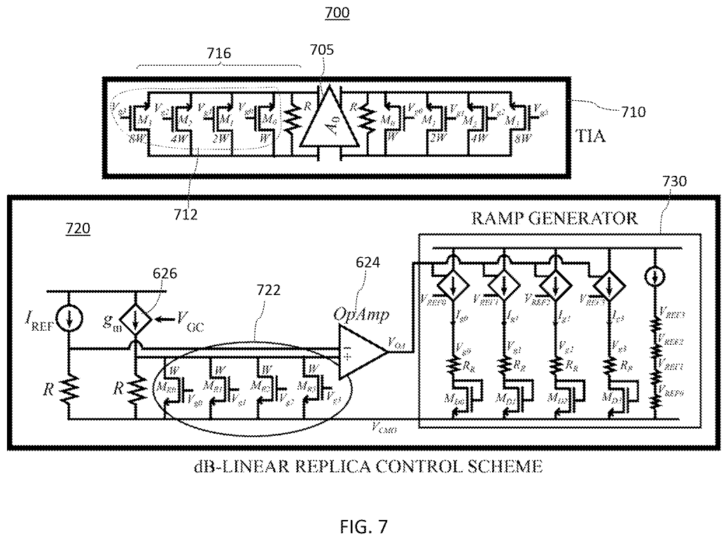

FIG. 7 shows a TIA apparatus 700 (“apparatus 700”) wherein the circuit in FIG. 6 is modified to (approximately) achieve dB-linear control. Similarly to the apparatus 600 shown in FIG. 6, the apparatus 700 of FIG. 7 includes a TIA 710 with a feedback resistor bank 716 (“RF bank 716”) shunting a voltage amplifier 705. The TIA feedback resistor bank 716, which is an embodiment of the feedback resistor bank 616 of FIG. 6A, includes a first set 712 of binary-weighted variable-resistors, four in the shown example. Each of the variable-resistors of the first set 712 may be implemented with a transistor, e.g. a MOSFET, same as in the TIA 610 of FIG. 6A. In operation, the variable-resistors of the first set 712, e.g. binary weighted MOSFETs Mᵢ, are turned on sequentially, e.g. as described above with reference to FIGS. 6A-6C. The variable-resistors of the first set 712 are controlled by a feedback control circuit 720 (“control circuit 720”), which adjusts, e.g. ramps, the gate voltages V_{gi} of the transistors Mᵢ to accurately set the feedback resistor value RF of the TIA 710 to a desired PVT-stable value. Similarly to the control circuit 620 of FIG. 6A, the control circuit 720 includes a reference set 722 of variable-resistors, e.g. MOSFETs M_{Ri}, and a ramp generator circuit 730. The ramp generator circuit 730, which may be an embodiment of the ramp generator circuit 630 of FIG. 6A, in operation generates multiple gate control voltages V_{gi}, i.e. the four voltages V_{g0}, V_{g1}, V_{g2}, V_{g3} in the illustrated embodiment, which are ramped to sequentially turn on the multiple variable-resistors Mᵢ of the first set 712.

The apparatus 700 of FIG. 7 is similar to the apparatus 600 of FIG. 6A, with the exception that, while the transistors M₀-M₃ of the first set 712 in the embodiment of FIG. 7 are binary weighted, the transistors M_{R}, of the reference set 722 (M_{R0}-M_{R3} in the illustrated example) have approximately the same gate width and/or channel resistances at same gate voltages. For this reason, the TIA feedback resistance RF of the TIA apparatus 700, e.g. the resistance of the TIA feedback resistor bank 710, varies approximately exponentially as a function of the gain control voltage V_{GC}, thereby allowing for (approximately) dB-linear control of the TIA transimpedance.

The TIA apparatus 600 and 700 may be modified to include a different number N of variable-resistors Mᵢ and M_{Ri} in the sets 712 and 722, i=1, . . . , N (N=4 in the examples of FIGS. 6A and 7). With a greater number of parallel variable-resistors in each set 712, 722, an exponential approximation for the RF versus the V_{GC} can be more accurate. For a moderate dB-linear accuracy and a dynamic range for typical high-speed TIAs, four variable-resistors in each set may be sufficient. A higher number of parallel elements in the set may result in a more complex layout and extra capacitive parasitics. Simulations show that the circuit of FIG. 7 may be capable of achieving an approximate log-linear (dB-linear) ZT control that is relatively insensitive to temperature and supply voltage variations during operation. These features may be useful for tunable-gain TIAs used, e.g., in optical receivers of optical communication systems, such as e.g. the coherent optical receiver illustrated in FIG. 1.

The loop gain of the feedback bias scheme is a function of the resistance of the reference set 622 or 722, and may significantly vary with the V_{GC} in embodiments where the desired RF tuning range is large. This can potentially cause a low phase margin at a maximum RF setting. The phase margin is the phase of the loop gain at the frequency for which the loop gain magnitude is equal to 0 dB. The phase margin should typically be between 60 and 180 degrees to reduce the AGC settling time and avoid ringing in the AGC response. While a solution to this problem could be to lower the gain of the OpAmp 624, this may result in a low loop gain at a minimum RF setting, which may reduce the accuracy of the ZT control and may increase the settling time of the loop.

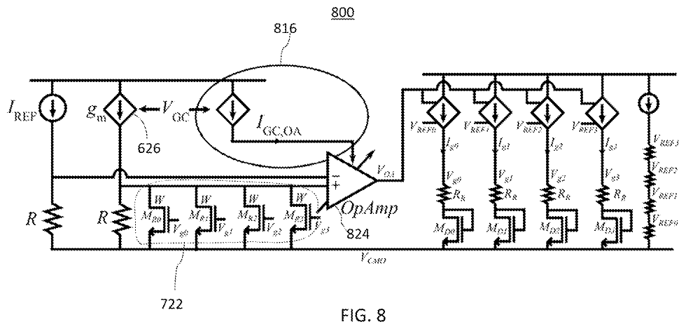

FIG. 8 illustrates a control circuit 800, which is an embodiment of the feedback control circuit 720 of FIG. 7 that includes a variable-gain OpAmp 824, which voltage gain A_{V,OA} is also controlled by the V_{GC} via a second VCCS 816. In an example control algorithm, the OpAmp gain A_{V,OA} and the gain of the feedback loop of the control circuit 800, may change in opposite directions as the V_{GC} varies. For example, the A_{V,OA} may be set to (or near) a maximum OpAmp gain at low V_{GC} and to (or near) a minimum OpAmp gain at high V_{GC}. In this way, the OpAmp gain variation may compensate the loop gain variation due to the variation of the reference resistor set 722. Using this scheme, loop gain and phase margin variation across V_{GC} range may be significantly reduced.

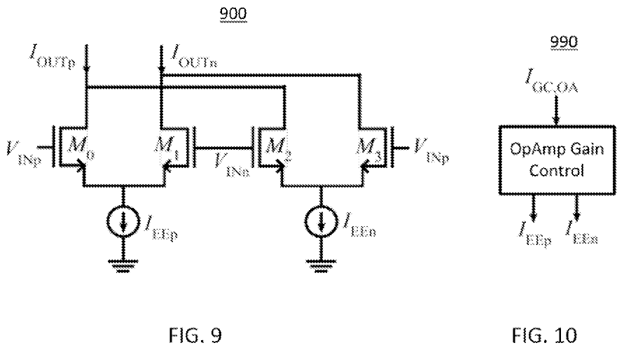

The OpAmp gain tuning can be realized in different ways. In some embodiments, the OpAmp 824 may have an input transconductor, e.g., such as an input transconductor 900 shown in FIG. 9. The input transconductor 900 may include, e.g., a main differential transistor pair (M₀/M₁) and a cross-coupled differential transistor pair (M₂/M₃). Two output currents I_{OUT}_{ₚ} and I_{OUT}_{ₙ} of the input transconductor 900 of FIG. 9 are provided to a second amplification stage (not shown), which outputs the output voltage V_{OA} of the OpAmp 824. The ratio of tail currents I_{EE}_{ₚ} and I_{EE}_{ₙ} of the differential transistor pairs M₀/M₁ and M₂/M₃ sets the input transconductance. Tail currents I_{EE}_{ₚ} and I_{EE}_{ₙ}, in turn, may be set by an OpAmp control block 990 to vary depending on the OpAmp gain control current I_{GC,OA}, as illustrated in FIG. 10. The current I_{GC,OA} is generated by the VCCS 826 of the control circuit 800 in dependence on the V_{GC}, as shown in FIG. 8. The scheme in FIG. 9 allows reducing the OpAmp gain without a significant impact on the OpAmp bandwidth (BW) and DC bias.

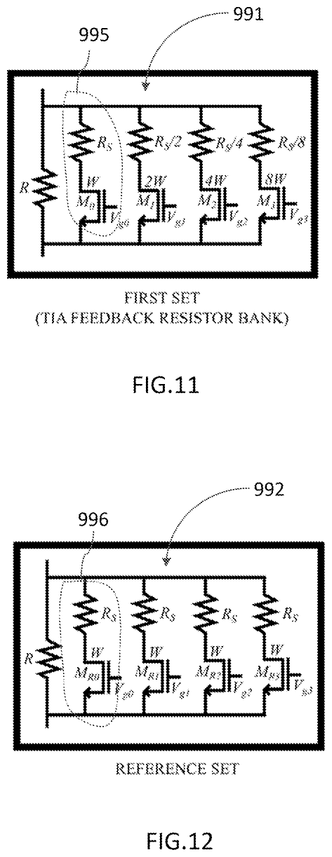

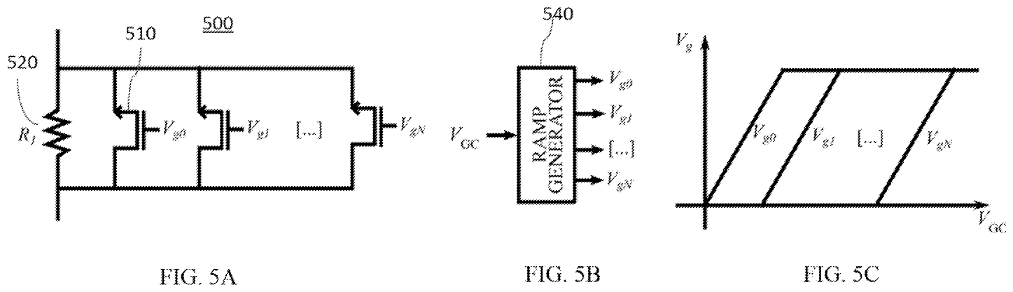

It will be understood by one skilled in the art that various changes in detail may be affected in the described embodiments without departing from the spirit and scope of the invention as defined by the claims. For example, although the example embodiments illustrated in FIGS. 6 and 7 refer to a differential input to differential output FE-TIA, in other embodiments the FE-TIA may have a single input to differential output configuration, a single input to single output (SISO) configuration, or a differential input to single output configuration, without significant differences on the feedback resistor control circuit. Some embodiments may use bipolar transistors instead of FET to implement any of the VCCS and gain stages. In some embodiments, resistors may be added in series with transistors M₁ and M_{Ri} in either one or both the FE-TIA variable resistance bank and the reference resistance bank; FIG. 11 illustrates a binary-weighted FE-TIA feedback resistor bank 991 in which variable-resistors 995 include fixed resistors having resistances that are scaled inversely with the gate widths of the corresponding transistors, while FIG. 12 illustrates a reference resistor bank 992 in which variable-resistors 996 include fixed resistors of approximately equal value. In some embodiments, diode-connected replica transistors M_{Di} in the ramp generator shown in FIGS. 6A, 7 and 8 may not be present, so that the ramp voltages V_{g,i} are generated by flowing currents I_{g,i} only through resistors R_{R}. In some embodiments, a technique alternative to the one shown in FIG. 10 may be used to vary the OpAmp gain with the current I_{GC,OA}. In some embodiments, a schematic different than the one shown in FIG. 6B may be used to implement the VCCS. In some embodiments, the OpAmp may be replaced by an Operational Transconductance Amplifier, i.e. an amplifier with large output impedance, without significant impact on the circuit operation.

It will be understood by one skilled in the art that various other changes in detail may be affected in the described examples without departing from the spirit and scope of the invention as defined by the claims.

1. An apparatus, comprising:
a transimpedance amplifier (TIA) comprising:
a voltage amplifier; and
a first set of variable-resistors connected in parallel as a variable shunt feedback to the voltage amplifier;
a control circuit connected to control the variable-resistors of the first set in a manner responsive to a TIA gain control voltage V_{GC}, the control circuit comprising a reference set of variable-resistors connected in parallel; and
a ramp generator configured to generate, responsive to an output voltage of the control circuit, a plurality of ramp voltages such that each of the voltages adjusts a corresponding one of the variable-resistors of the first set and the reference set.

2. The apparatus of claim 1, wherein each of the variable-resistors of the first set comprises a field-effect transistor (FET), channel resistances of different ones of the FETs having different values for a same applied gate voltage, ratios of different ones of said values being approximately equal to nonzero integer powers of two.

3. The apparatus of claim 1, wherein each of the variable-resistors of the first set comprises a field-effect transistor (FET), gate widths of different ones of the FETs having different values, ratios of different ones of said values being approximately equal to nonzero integer powers of two.

4. The apparatus of claim 2, wherein at least some of the variable-resistors of the first set comprise each a resistor in series with the FET of a corresponding one of the variable resistors of the first set, ratios of resistances of said resistors of different ones of the variable-resistors being approximately equal to nonzero integer powers of two.

5. The apparatus of claim 2, wherein each of the variable-resistors of the reference set comprises a field-effect transistor (FET), channel resistances of different ones of the field effect transistors of the reference set being about the same for a same gate voltage applied thereto.

6. The apparatus of claim 3, wherein each of the variable-resistors of the reference set comprises a FET, gate widths of different ones of the FETs of the reference set being about the same.

7. The apparatus of claim 5, wherein each of the variable-resistors of the reference set comprises a resistor in series with a corresponding one of the FETs of the reference set, said resistors of the reference set having about a same resistance.

8. The apparatus of claim 1, wherein the control circuit comprises a voltage-controlled current source configured to transmit a current proportional to V_{GC} to an input of the reference set.

9. The apparatus of claim 1 wherein the gain control circuit comprises an operational amplifier having a first input connected to the reference set and a second input connected to a reference voltage V_{REF}.

10. The apparatus of claim 9 configured to vary a voltage gain A_{V} of the operational amplifier responsive to the TIA gain control voltage V_{GC}.

11. The apparatus of claim 10 wherein the control circuit is configured to vary the voltage gain A_{V} of the operational amplifier approximately proportionally to an inverse of the resistance of the reference set.

12. The apparatus of claim 1, wherein the control circuit is configured to vary a resistance of the first set in an approximately exponential relationship to the gain control voltage V_{GC}.

13. The apparatus of claim 1, wherein the ramp generator comprises a set of voltage-controlled current sources, each configured to provide an output current to a resistor to generate one of the ramp voltages, each of the output currents being based on the output voltage of the control circuit and an offset voltage V_{REFj}, the offset voltages V_{REFj} being different for different ones of the ramp voltages.

14. A coherent optical receiver comprising an optical hybrid; a pair of photodiodes; and the apparatus of claim 1; and
wherein each photodiode is configured to receive light from a corresponding output of the optical hybrid; and
wherein each of the photodiodes is connected to a corresponding input of the transimpedance amplifier.
